(19) United States
(12) Patent Application Publication
(10) Pub. No.: US 2020/0379011 A1
(43) Pub. Date: Dec. 3, 2020

(54) TEST FIXTURE AND TESTING MACHINE HAVING THE SAME

(71) Applicant: TRIPLE WIN TECHNOLOGY(SHENZHEN) CO.LTD., Shenzhen (CN)

(72) Inventor: YANG-GANG LIU, Shenzhen (CN)

(21) Appl. No.: 16/524,413

(22) Filed: Jul. 29, 2019

(30) Foreign Application Priority Data
May 31, 2019 (CN) 201910471891.1

(51) Int. Cl. G01R 1/073; G01R 31/28

(52) U.S. Cl. CPC G01R 1/07335; G01R 31/2808; G01R 31/2805; G01R 1/07392

(57) ABSTRACT

A test fixture holding without risk of any surface marking or damage to a product being tested includes a base with a circuit board, a needle seat, and a side push structure. The needle seat includes probes and first receiving cavity for holding the product. An opening in a sidewall of the first receiving cavity exposes one end of the side push structure. One end of the probe connects with the circuit board, other end of the probe is in the needle seat. With product in the first receiving cavity, the side push structure pushes the product against the sidewalls and the product is depressed to abut against the needle seat and the needles which are moved into the first receiving cavity to make contact with to the product. A testing machine having the test fixture is also provided.

### FIELD

The subject matter herein generally relates to test fixture and a testing machine having the same.

### BACKGROUND

When a product is placed on a test fixture for testing, in order to accurately position the product, the end cap of the test fixture is provided with a push block and a press block. During the pressing of the end cap to the fixture, the push block pushes the product to move, and the press block on the end cap presses down the product. However, when the product is pressed under the press block, the product may not be pushed to the exact position, so that the press block may not mesh with the product geometrically. Such inaccuracy may result in damage to the surface of the product.

In view of this, a design of a test fixture to prevent the surface of the product from being scratched or crushed when testing the product maybe desired. A test machine having the test fixture is also provided.

### BRIEF DESCRIPTION OF THE DRAWINGS

Implementations of the present technology will now be described, by way of embodiments, with reference to the attached figures.

FIG. 1 is an assembled, isometric view of a test fixture in accordance with an embodiment of the present disclosure.

FIG. 2 is an exposed, isometric view of the test fixture in FIG. 1.

FIG. 3 is a plan view of the test fixture in FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “substantially” is defined to mean essentially conforming to the particular dimension, shape, or other feature that the term modifies, such that the component need not to be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series, and the like.

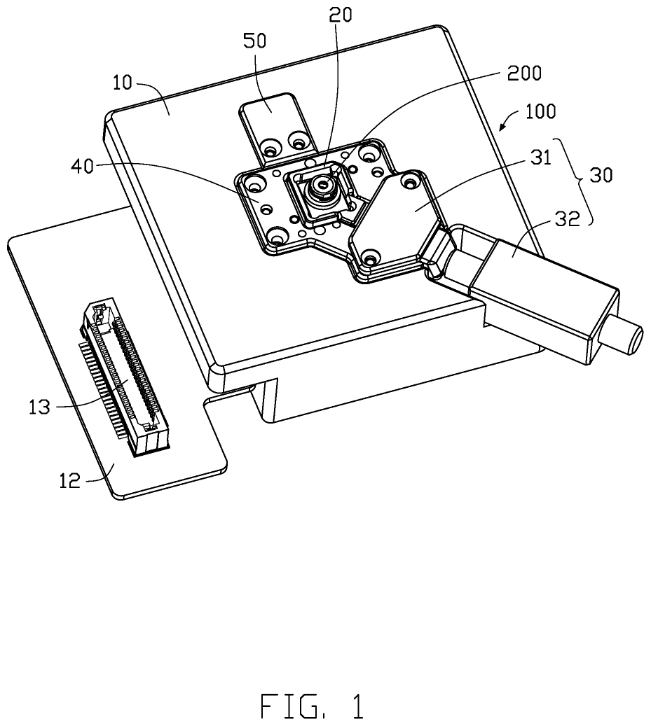

Referring to FIG. 1, a testing machine of an embodiment in the present disclosure is for testing a product 200. The product 200 is a single finished product in a photographic module. Specifically, the test machine includes a test fixture 100 that receives the product 200 being tested.

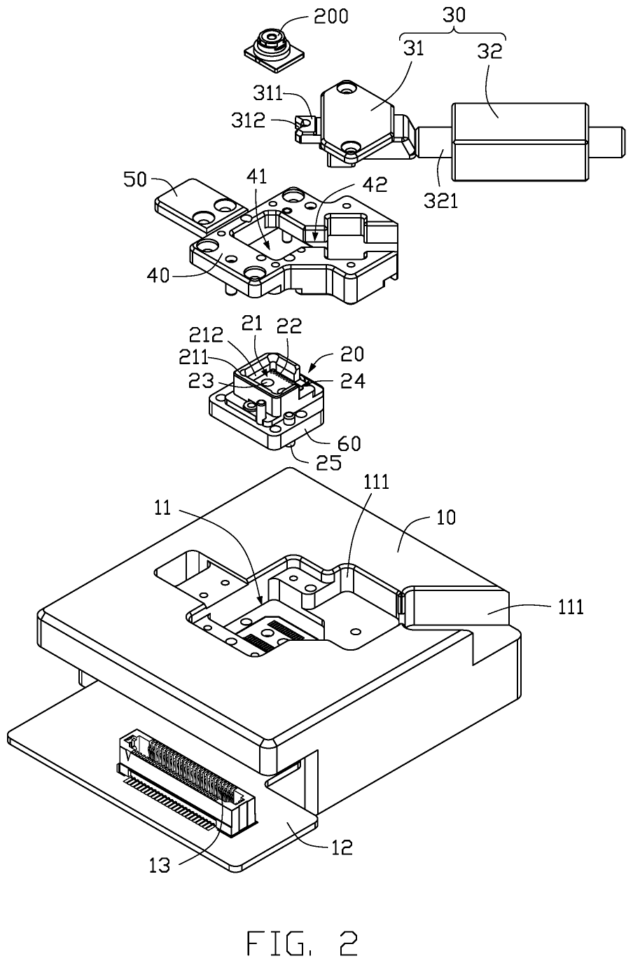

Referring to FIG. 1 and FIG. 2, the test fixture 100 includes a base 10, a needle seat 20, and a side push structure 30. The needle seat 20 and the side push structure 30 are disposed on the base 10. The needle seat 20 is provided with a plurality of probes 22 and a first receiving cavity 21. An opening 24 is defined in an edge portion of a sidewall 212 which forms the first receiving cavity 21. The first receiving cavity 21 is configured to receive the product 200. One end of the side push structure 30 is positioned in the opening 24 for pushing the product 200. The base 10 is provided with a circuit board 12 thereon. One end of each of the probes 22 connects with the circuit board 12, and another end of the probe 22 is received in the needle seat 20.

When the product 200 is taken in the first receiving cavity 21, the side push structure 30 is driven to push the product 200 to abut against inner sides of the sidewalls 212 which form the first receiving cavity 21. The product 200 is depressed under an external force to abut against the needle seat 20, such that the needle seat 20 moves relative to the base 10 to force the another end of the probe 22 protrudes into the first receiving cavity 21 to connect with the product 200.

Referring to FIG. 2, a chamber 11 is defined in the base 10. The base 10 is recessed from an end surface of the base 10. The needle seat 20 and the side push structure 30 are held in the chamber 11. An inner contour of the chamber 11 is matched to hold the needle seat 20 and the side push structure 30. The circuit board 12 is positioned at an end of the base 10 away from the needle seat 20 and the side push structure 30. The needle seat 20 and the circuit board 12 are located on opposite ends of the base 10, such that the probe 22 connects with the circuit board 12. When the product 200 is depressed under the external force, the probes 22 protrude into the first receiving cavity 21 to make contact with the product 200.

Specifically, a limiting portion 111 is disposed at an edge portion of the chamber 11 for abutting and guiding the side push structure 30. The product 200 is provided with a connecting portion (not shown), and the circuit board 12 is provided with another connecting portion (not shown). The connecting portion of the product 200 connects with the connection portion of the circuit board 12 through the probes 22. It can be understood that the probes 22 can be connected to the circuit board 12 by soldering, but the manner of connection of the probes 22 and the circuit board 12 is not limited thereto.

Referring to FIG. 2, a connector 13 is provided on the circuit board 12. The connector 13 is for connection with other components in the testing machine to enable the test fixture 100 to be coupled to the testing machine.

Referring to FIG. 2, the probes 22 are disposed on the bottom of the first receiving cavity 21. Each probe 22 extends towards the circuit board 12. The end of the probe 22 adjacent to the circuit board 12 connects with the circuit board 12, and the other end of probe 22 is received in the needle seat 20 when the needle seat 20 is resting relative to the base 10. In an embodiment, the needle seat 20 is provided with two rows of the probes 22, and a predetermined width is designed between the two rows of the probes 22. The first receiving cavity 21 is substantially square. Corners 211 of the first receiving cavity 21 are rounded corners. Each of the two adjacent sidewalls 212 protrudes from the center of the first receiving cavity 21 by a predetermined distance, such that when the product 200 is placed in the first receiving cavity 21, the sidewalls 212 abut against the product 200, and the corners 211 will not scratch or bump the product 200. The opening 24 is disposed at one of the corners 211 of the first receiving cavity 21. It is understood that the position of the opening 24 is not limited thereto.

The needle seat 20 is further provided with at least one suction hole 23 in the first receiving cavity 21. The suction hole 23 is defined in the bottom of the first receiving cavity 21. In an embodiment, the needle seat 20 has two suction holes 23. In other embodiments, number of suction holes 23 may be different. A vacuum pipe 25 is disposed in each of the suction holes 23. The vacuum pipe 25 extends away from the first receiving cavity 21. When the product 200 is pushed by the side push structure 30 to abut against the sidewalls 212, gas is taken from the vacuum pipe 25 so that an adsorption force is applied to the product 200 through the suction hole 23, such that the product 200 depresses the needle seat 20.

It can be understood that, in other embodiments, force can be applied to the product 200 through other means, such as clamping lateral surfaces of the product 200 and pulling the product 200 downward, such that the product 200 is pressed down towards the needle seat 20. In the embodiment, the product 200 is attracted through the adsorption of the vacuum pipes 25, without directly pressing against the surface of the product 200. Damage to the product 200 is thus avoided.

Referring to FIG. 2, preferably, the needle seat 20 is disposed on the base 10 through a fixing block 60. If the product 200 is replaced, the needle seat 20 may be replaced along with the product 200. At this time, the fixed block 60 can be replaced and the base 10 can be used continuously. In another embodiment, the fixing block 60 can be eliminated, and the needle seat 20 can be directly disposed on the base 10.

Referring to FIG. 2, the side push structure 30 includes a side push block 31 and a cylinder 32. The cylinder 32 connects with the side push block 31. The side push block 31 is for pushing the product 200, and the cylinder 32 is for driving the side push block 31. The side push block 31 and the cylinder 32 are held in the chamber 11. The limiting portion 111 abuts against the side push block 31 to avoid the side push block 31 moving, and abuts against the cylinder 32 to limit the extending direction of a push rod 321, thereby avoiding skewing of the push rod 321.

Further, the side push block 31 is provided with a push portion 311. The push portion 311 and the cylinder 32 are disposed at opposite ends of the side push block 31. The push portion 311 is disposed in the opening 24. When the side push structure 30 is to push the product 200, the cylinder 32 drives the push portion 311 by the push rod 321 to cause the push portion 311 to push the product 200. A push surface 311 of the push portion 311 contacting the product 200 contacts outer sidewalls of the product 200. Preferably, the push surface 312 contacts two adjacent outer sidewalls of the product 200 to enable the product 200 promoted well.

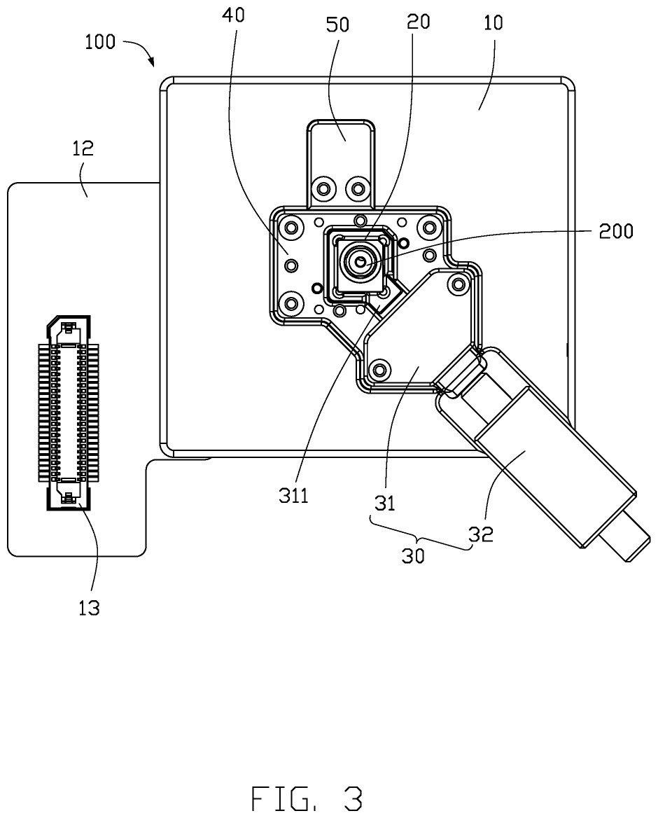

Referring to FIG. 2 and FIG. 3, preferably, in an embodiment, the test fixture 100 may further include a first limiting block 40. The first limiting block 40 is disposed on the base 10. A second receiving cavity 41 is defined in the first limiting block 40, and the needle seat 20 is held in the second receiving cavity 41. Correspondingly, the first limiting block 40 is provided with a loophole 42 at a corresponding position of the opening 24, such that the push portion 311 can be disposed in the loophole 42. It can be understood that, in other embodiments, the first limiting block 40 and the side push block 31 can be an integrally formed structure. If the first limiting block 40 is not required to be disposed, the first limiting block 40 can be separately designed from the side push block 31, the first limiting block 40 can be cancelled, and the needle seat 20 can be directly disposed on the base 10.

Referring to FIG. 2 and FIG. 3, preferably, in an embodiment, the test fixture 100 may further include a second limiting block 50. The second limiting block 50 is disposed on the base 10, and one end of the second limiting block 50 abuts against the first limiting block 40.

It can be understood that when the base 10 fixes the first limiting block 40, the second limiting block 50 can be omitted. Further, the first limiting block 40 and the second limiting block 50 are disposed on the base 10 for reducing the number of components needing to be changed for accommodating other products, other products having a different shape. As far as possible, the components in the test fixture 100 can be reused, and when other products are to be received and tested, it is only necessary to replace a small number of components. For example, the needle seat 20 is fixed only by adjusting the structures of the first limiting block 40 and the second limiting block 50.

It can be understood that the contact surface between the side push structure 30 and the product 200 and the contact surface between the needle seat 20 and the first limiting block 40 are relatively smooth. When the vacuum pipe 25 adsorbs the product 200 downward, the suction force generated by the vacuum pipe 25 is greater than the friction between the product 200 and the side push structure 30 and the friction between the needle seat 20 and the first limiting block 40.

Referring to FIG. 1, the side push structure 30 pushes the product 200 after the product 200 is placed into the needle seat 20. Specifically, the cylinder 32 drives the push portion 311 of the side push block 31 to push the product 200 to abut against the sidewalls 212. The vacuum pipe 25 absorbs the product 200 through the suction hole 23 to drive the product 200 and so depress needle seat 20, such that one end of each of the probes 22 protrudes into the first receiving cavity 21 to make contact with the product 200.

If the product 200 passes, the product 200 is illuminated after the probes 22 are coupled to the product 200. At this time, the center of the product 200 abutting on the needle seat 20 is aligned with the center of a resolution test card (camera test chart, not shown), and the test is performed by the resolution test card.

The test fixture 100 and the testing machine provided in the embodiment of the present disclosure push the product 200 held in the needle seat 20 through the side push structure 30, such that the product 200 abuts against the sidewalls 212, and apply a downward force to the product 200 by vacuum suction to depress the needle seat 20, thereby the probes 22 on the needle seat 20 can function to detect the product 200. In the present disclosure, an upper surface of the product 200 is not pressed when the product 200 is depressed downward, thereby avoiding scratches or marks or other damage to the surface of the product 200.

The embodiments shown and described above are only examples. Many details are often found in the art. Therefore, many such details are neither shown nor described. Even though numerous characteristics and advantages of the present technology have been set forth in the foregoing description, together with details of the structure and function of the present disclosure, the disclosure is illustrative only, and changes may be made in the details, including in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A test fixture for testing a product, comprising:
a base provided with a circuit board thereon;
a needle seat disposed on the base, the needle seat comprising a plurality of probes and a first receiving cavity configured for holding the product; and
a side push structure disposed on the base; and
wherein an opening is defined in an edge portion of sidewalls, the sidewalls define the first receiving cavity; one end of the side push structure is positioned in the opening, the side push structure is configured for pushing the product; one end of each of the probes is connected to the circuit board, and another end of the probe is received in the needle seat; and
wherein when the product is placed in the first receiving cavity, the side push structure is driven to push the product to abut against inner sides of the sidewalls; the product is depressed under an external force to abut against the needle seat, such that the needle seat moves relative to the base to force the another end of the probe protrudes into the first receiving cavity to couple to the product.

2. The test fixture of claim 1, wherein the side push structure comprises a side push block and a cylinder connected with the side push block; the side push block is configured for pushing the product, and the cylinder is configured for driving the side push block.

3. The test fixture of claim 2, wherein the side push block comprises a push portion, the push portion is disposed in the opening; when the side push structure pushes the product, the push portion contacts and pushes the product.

4. The test fixture of claim 3, further comprising a limiting block, wherein the limiting block is disposed on the base; a second receiving cavity is defined in the limiting block, and the needle seat is held in the second receiving cavity.

5. The test fixture of claim 4, wherein the limiting block comprises a loophole at a corresponding position of the opening, and the push portion is disposed in the loophole.

6. The test fixture of claim 1, wherein the needle seat further comprises at least one suction hole, a vacuum pipe is disposed in each of the suction holes; when the product is pushed by the side push structure to abut against the sidewalls, the vacuum pipe starts to vacuumize and applies an adsorption force to the product through the suction hole, such that the product depresses the needle seat.

7. The test fixture of claim 1, wherein a chamber is defined in the base, the needle seat and the side push structure are held in the chamber; and an inner contour of the chamber is matched to hold the needle seat and the side push structure.

8. The test fixture of claim 7, wherein the needle seat and the circuit board are located on opposite ends of the base, such that the probe are connected with the circuit board.

9. The test fixture of claim 8, wherein a connector is provided on the circuit board; the test fixture is coupled to external components through the connector.

10. A testing machine, comprising:
a test fixture for testing a product, the test fixture comprising:
a base provided with a circuit board thereon;
a needle seat disposed on the base, the needle seat comprising a plurality of probes and a first receiving cavity for holding the product; and
a side push structure disposed on the base; and
wherein an opening is defined in an edge portion of sidewalls, the sidewalls define the first receiving cavity; one end of the side push structure is positioned in the opening for pushing the product; one end of each of the probes connects with the circuit board, and another end of the probe is received in the needle seat; and
wherein when the product is placed in the first receiving cavity, the side push structure is driven to push the product to abut against inner sides of the sidewalls; the product is depressed under an external force to abut against the needle seat, such that the needle seat moves relative to the base to force the another end of the probe protrudes into the first receiving cavity to couple to the product.

11. The testing machine of claim 10, wherein the side push structure comprises a side push block and a cylinder connected with the side push block; the side push block is configured for pushing the product, and the cylinder is configured for driving the side push block.

12. The testing machine of claim 11, wherein the side push block comprises a push portion, the push portion is disposed in the opening; when the side push structure pushes the product, the push portion contacts and pushes the product.

13. The testing machine of claim 12, further comprising a limiting block, wherein the limiting block is disposed on the base; a second receiving cavity is defined in the limiting block, and the needle seat is held in the second receiving cavity.

14. The testing machine of claim 13, wherein the limiting block comprises a loophole at a corresponding position of the opening, and the push portion is disposed in the loophole.

15. The testing machine of claim 10, wherein the needle seat further comprises at least one suction hole, a vacuum pipe is disposed in each of the suction holes; when the product is pushed by the side push structure to abut against the sidewalls, the vacuum pipe starts to vacuumize and applies an adsorption force to the product through the suction hole, such that the product depresses the needle seat.

16. The testing machine of claim 10, wherein a chamber is defined in the base, the needle seat and the side push structure are held in the chamber; and an inner contour of the chamber is matched to hold the needle seat and the side push structure.

17. The testing machine of claim 16, wherein the needle seat and the circuit board are located on opposite ends of the base, such that the probe are connected with the circuit board.

18. The testing machine of claim 17, wherein a connector is provided on the circuit board; the test fixture is adapted for coupling to other components of the testing machine through the connector.
